(19) United States
(12) Patent Application Publication
(10) Pub. No.: US 2025/0351728 A1
(43) Pub. Date: Nov. 13, 2025

(54) DIE, METHOD FOR MANUFACTURING DIE, DROPLET EJECTION HEAD, AND DROPLET EJECTION DEVICE

(71) Applicant: Konica Minolta, Inc., Tokyo (JP)

(72) Inventors: Yuji MATSUSHITA, Hachioji-shi, Tokyo (JP); Shintaro HARA, Hachioji-shi, Tokyo (JP); Hideki MASHIMA, Sagamihara-shi, Kanagawa (JP)

(21) Appl. No.: 18/871,517

(22) PCT Filed: May 25, 2023
(86) PCT No.: PCT/JP2023/019494

§ 371 Date: Dec. 4, 2024

(30) Foreign Application Priority Data
Jun. 8, 2022 (JP) 2022-092626

(51) Int. Cl. H10N 30/20; B41J 2/14; H10N 30/088; H10N 30/853; H10N 30/87

(52) U.S. Cl. CPC H10N 30/20; H10N 30/853; H10N 30/87; B41J 2/14201; H10N 30/088

(57) ABSTRACT

The present invention addresses the problem of providing a die in which the occurrence of cracks is suppressed, a method for manufacturing the die, and a droplet ejection head and a droplet ejection device both equipped with the die. The die of the present invention comprises a piezoelectric actuator having a piezoelectric element and a hollow portion which provides a pressure chamber. The piezoelectric element comprises at least a piezoelectric film, a first electrode positioned over the piezoelectric film, and a second electrode positioned under the piezoelectric film. In the piezoelectric actuator, the second electrode doubles as a vibration plate, or a vibration plate is separately provided under the second electrode. The hollow portion is positioned under the second electrode doubling as the vibration plate or under the separately provided vibration plate. The piezoelectric film has a major surface which is a (001) plane, wherein the crystal orientation is aligned in a major surface out-of-plane direction and a major surface in-plane direction. When the longitudinal direction of the hollow portion when viewed from the major surface out-of-plane direction of the piezoelectric film is a first direction and the [100] direction of the piezoelectric film is a second direction, an acute angle θ1 formed by the first direction and the second direction is within a range of 30° to 60°.

### TECHNICAL FIELD

The present invention relates to a die, a method for manufacturing a die, a droplet ejection head, and a droplet ejection device. More specifically, the present invention relates to a die or the like in which occurrence of a crack is suppressed.

### BACKGROUND ART

A single chip in which elements, wirings, and the like are integrated, such as a droplet ejection head chip, is referred to as a “die” in the semiconductor field. In a die that includes a piezoelectric actuator, the piezoelectric actuator may include a piezoelectric element and a hollow portion (a portion serving as a pressure chamber) in a shape having a longitudinal direction and a lateral direction like an oval. As a piezoelectric film of the piezoelectric element included in the piezoelectric actuator, a piezoelectric film whose crystal orientation is aligned at least in an out-of-plane direction of a main surface of the piezoelectric film is often used (See, e.g., Patent Documents 1, 2). There is also disclosed a technique in which a piezoelectric film whose crystal orientations are aligned not only in an out-of-plane direction of a main surface of the piezoelectric film but also in an in-plane direction of the main surface of the piezoelectric film is used (See, e.g., Patent Document 3).

The piezoelectric film in which the crystal orientations are aligned not only in an out-of-plane direction of the main surface but also in an in-plane direction of the main surface has an advantage that piezoelectric properties are excellent, but has a problem that a crack easily occurs when a voltage is applied. A crack generated in the piezoelectric film of the die degrades performance of a device that includes the die. For example, in the case of a droplet ejection device that includes a die as a droplet ejection head chip, a crack generated in the piezoelectric film reduces ejection stability of the droplet ejection device.

### CITATION LIST

### Patent Literature

Patent Document 1: JP 2007-042983A
Patent Document 2: JP 2003-179279A
Patent Document 3: JP 2006-173646A

### SUMMARY OF INVENTION

### Technical Problem

The present invention has been conceived in consideration of the above-described problem and situation. It is an object of the present invention to provide a die in which the occurrence of a crack is suppressed, a method for manufacturing the die, and a droplet ejection head and a droplet ejection device that includes the die.

### Solution to Problem

In order to solve the above-described problem, the present inventors have studied the causes of the above-described problem, and the like. As a result, the present inventors have found that in a die that includes a piezoelectric actuator having a piezoelectric element and a hollow portion serving as a pressure chamber, the occurrence of a crack can be suppressed by limiting, to a certain range, the magnitude of an acute angle between a [100] direction of a piezoelectric film and the longitudinal direction of the hollow portion or the direction in which the piezoelectric actuator is arranged, and thus arrived at the present invention.

That is, the object of the present invention described above is achieved by the following means.
1. A die comprising one or more piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ1 between a first direction and a second direction is within a range of 30 to 60° where the first direction is a longitudinal direction of the hollow portion as viewed from the out-of-plane direction of the main surface of the piezoelectric film and the second direction is a [100] direction of the piezoelectric film.
2. The die described in Item 1, wherein the acute angle θ1 is within a range of 40 to 50°.
3. A die comprising a plurality of piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ2 between a third direction and a second direction is within a range of 30 to 60° where the third direction is a direction in which the plurality of piezoelectric actuators are arranged and the second direction is a [100] direction of the piezoelectric film.
4. The die described in Item 3, wherein the acute angle θ2 is within a range of 40 to 50°.
5. The die described in any one of Items 1 to 4, wherein a distance between the first electrode and the second electrode in the piezoelectric element is within a range of 0.1 to 5 μm.
6. The die described in any one of Items 1 to 4, wherein: the piezoelectric element includes a dielectric film between the piezoelectric film and the second electrode; the dielectric film has crystal orientations aligned in an out-of-plane direction of a main surface of the dielectric film and an in-plane direction of the main surface of the dielectric film; the aligned out-of-plane crystal orientation of the piezoelectric film coincides with the aligned out-of-plane crystal orientation of the dielectric film; and the aligned in-plane crystal orientation of the piezoelectric film coincides with the aligned in-plane crystal orientation of the dielectric film.
7. The die described in any one of Items 1 to 4, wherein: the first electrode has a multilayer structure; a lowermost layer of the first electrode having the multilayer structure, the lowermost layer being closest to the piezoelectric film, has crystal orientations aligned in an out-of-plane direction of a main surface of the lowermost layer and an in-plane direction of the main surface of the lowermost layer; the aligned out-of-plane crystal orientation of the piezoelectric film coincides with the aligned out-of-plane crystal orientation of the lowermost layer; and the aligned in-plane crystal orientation of the piezoelectric film does not coincide with the aligned in-plane crystal orientation of the lowermost layer.
8. The die described in any one of Items 1 to 4, wherein: the piezoelectric element includes a dielectric film between the piezoelectric film and the second electrode; the first electrode has a multilayer structure; and the piezoelectric film, the dielectric film, and a lowermost layer of the first electrode having the multilayer structure, the lowermost layer being closest to the piezoelectric film, all have a perovskite structure represented by ABO₃.
9. The die described in any one of Items 1 to 4, wherein the piezoelectric film is a lead zirconate titanate film.
10. The die described in any one of Items 1 to 4, wherein the piezoelectric element includes a dielectric film between the piezoelectric film and the second electrode, the dielectric film is a lead lanthanum titanate film, the first electrode has a multilayer structure, and a lowermost layer of the first electrode having the multilayer structure, the lowermost layer being closest to the piezoelectric film, is a strontium ruthenate film or a lanthanum nickelate film.
11. The die described in any one of Items 1 to 4, wherein an upper surface of the first electrode is covered with a protective film, and the protective film is a zirconium dioxide film, an aluminum oxide film, a hafnium oxide film, an yttrium oxide film, or an aluminum nitride film.
12. A method for manufacturing a die using a Si substrate, the method comprising at least steps of: forming a stacked body that includes the die described in any one of Items 1 to 4 on the Si substrate; and cutting the stacked body to individualize the die, wherein an acute angle θ3 between a fourth direction and a fifth direction is within a range of 0 to 15° where the fourth direction is a vertical direction of a notch or an orientation flat of the Si substrate and the fifth direction is a cutting direction forming a smallest angle with the fourth direction among cutting directions in the cutting.
13. The method described in Item 12, wherein the acute angle θ3 is within a range of 0 to 5°.
14. A droplet ejection head comprising a die, wherein the die is the die described in any one of Items 1 to 4.
15. A droplet ejection device comprising a droplet ejection head, wherein the droplet ejection head is the droplet ejection head described in Item 14.

### Advantageous Effects of Invention

With the above-described means of the present invention, it is possible to provide a die in which the occurrence of a crack is suppressed, a method for manufacturing the die, and a droplet ejection head and a droplet ejection device that includes the die.

The mechanism by which the effect of the present invention is manifested or by which the effect of the present invention works is inferred as follows.

As the cause of a crack easily generated in a piezoelectric film of a piezoelectric actuator, where crystal orientations of the piezoelectric film are aligned in an out-of-plane direction of the main surface and an in-plane direction of the main surface, the present inventors focused on the crystal structure of the piezoelectric film, the shape of the piezoelectric actuator, and the arrangement of the piezoelectric actuators.

The present inventors have found that, regarding the crystal structure of the piezoelectric film, when the main surface is a (001) plane, a crack is more likely to occur in a [100] direction and a [010] direction in an piezoelectric film in which the crystal structure is aligned in an in-plane direction of the main surface than in a piezoelectric film in which the crystal structure is not aligned in an in-plane direction of the main surface. Furthermore, the present inventors have found that, regarding the shape of the piezoelectric actuator, when the hollow portion of the piezoelectric actuator has a longitudinal direction and a lateral direction, such as an oval, a rectangle, an ellipse, a rhombus, or the like, a crack is likely occur in the piezoelectric film in the longitudinal direction and the lateral direction.

Based on these discoveries, for the die according to an embodiment of the present invention, the acute angle θ1 between the longitudinal direction (first direction) of the hollow portion and the [100] direction (second direction) of the piezoelectric film is specified to be within a range of 30 to 60° in order to suppress the occurrence of a crack. In the die in which the range of θ1 is specified as described above, since there is a difference between the direction in which a crack is likely to occur from the viewpoint of the shape of the piezoelectric actuator and the direction in which a crack is likely to occur from the viewpoint of the crystal structure of the piezoelectric film, the occurrence of a crack is suppressed.

In addition, the present inventors have found that, regarding the arrangement of the piezoelectric actuators in the die, a crack is likely to occur in the piezoelectric film in a direction in which the plurality of piezoelectric actuators are arranged.

Based on this discovery, for the die according to an embodiment of the present invention, the acute angle θ2 between the direction in which the plurality of piezoelectric actuators are arranged (third direction) and the [100] direction of the piezoelectric film (second direction) is specified to be within a range of 30 to 60° in order to suppress the occurrence of a crack. In the die in which the range of θ2 is specified as described above, since there is a difference between the direction in which a crack is likely to occur from the viewpoint of the arrangement of the piezoelectric actuators and the direction in which a crack is likely to occur from the viewpoint of the crystal structure of the piezoelectric film, the occurrence of a crack is suppressed.

Due to such a manifestation mechanism or working mechanism, it is possible to provide a die or the like in which the occurrence of a crack is suppressed.

### BRIEF DESCRIPTION OF DRAWINGS

FIG. 1 This is a schematic plan view of a die viewed from bottom (side facing hollow portions).

FIG. 2 This is a schematic cross-sectional view of a part of the die.

FIG. 3 This is a diagram illustrating a layer configuration of a piezoelectric actuator when a second electrode also serves as a vibration plate.

FIG. 4 This is a diagram illustrating a layer configuration of a piezoelectric actuator when a vibration plate is separately provided under a second electrode.

FIG. 5 This is an electron micrograph in which cracks generated in a [100] direction (second direction) and a [010] direction (in-plane perpendicular direction to the second direction) of a piezoelectric film are observed.

FIG. 6 This is a diagram illustrating an acute angle θ1.

FIG. 7 This is a diagram illustrating an acute angle θ2.

FIG. 8 This is a diagram illustrating an acute angle θ3.

### DESCRIPTION OF EMBODIMENTS

The die according to one embodiment of the present invention comprises one or more piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ1 between a first direction and a second direction is within a range of 30 to 60° where the first direction is a longitudinal direction of the hollow portion as viewed from the out-of-plane direction of the main surface of the piezoelectric film and the second direction is a [100] direction of the piezoelectric film.

The die according to another embodiment of the present invention comprises a plurality of piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ2 between a third direction and a second direction is within a range of 30 to 60° where the third direction is a direction in which the plurality of piezoelectric actuators are arranged and the second direction is a [100] direction of the piezoelectric film.

These features are technical features common to or corresponding to the following embodiments.

For an embodiment of the die according to the present invention, it is preferable from the viewpoint of further suppressing the occurrence of a crack that the acute angle θ1 is within a range of 40 to 50°.

For an embodiment of the die according to the present invention, it is preferable from the viewpoint of further suppressing the occurrence of a crack that the acute angle θ2 is within a range of 40 to 50°.

For an embodiment of the die according to the present invention, it is preferable from the viewpoint of a displacement generating force required of the piezoelectric element that a distance between the first electrode and the second electrode in the piezoelectric element is within a range of 0.1 to 5 μm.

For an embodiment of the die according to the present invention, it is preferable from the viewpoint of the dielectric constant that the piezoelectric element includes a dielectric film between the piezoelectric film and the second electrode, the dielectric film has crystal orientations aligned in an out-of-plane direction of the main surface of the dielectric film and an in-plane direction of the main surface of the dielectric film, the aligned out-of-plane crystal orientation of the piezoelectric film coincides with the aligned out-of-plane crystal orientation of the dielectric film, and the aligned in-plane crystal orientation of the piezoelectric film also coincides with the aligned in-plane crystal orientation of the dielectric film.

For an embodiment of the die according to the present invention, it is preferable from the viewpoint of piezoelectric properties that the first electrode has a multilayer structure, and the lowermost layer of the multilayered first electrode, where the lowermost layer is located closest to the piezoelectric film, has crystal orientations aligned in an out-of-plane direction of the main surface of the lowermost layer and an in-plane direction of the main surface of the lowermost layer, and the aligned out-of-plane crystal orientation of the piezoelectric film coincides with the aligned out-of-plane crystal orientation of the lowermost layer, and the aligned in-plane crystal orientation of the piezoelectric film does not coincide with the aligned in-plane crystal orientation of the lowermost layer.

For an embodiment of the die according to the present invention, it is preferable from the viewpoint of piezoelectric properties that the piezoelectric element includes a dielectric film between the piezoelectric film and the second electrode, the first electrode has a multilayer structure, and the piezoelectric film, the dielectric film, and the lowermost layer of the multilayered first electrode, where the lowermost layer is located closest to the piezoelectric film, all have a perovskite structure represented by ABO₃.

For an embodiment of the die according to the present invention, it is preferable from the viewpoint of piezoelectric properties that the piezoelectric film is a lead zirconate titanate film.

For an embodiment of the die according to the present invention, it is preferable from the viewpoint of piezoelectric properties that the piezoelectric element includes a dielectric film between the piezoelectric film and the second electrode, the dielectric film is a lead lanthanum titanate film, the first electrode has a multilayer structure, and the lowermost layer of the multilayered first electrode, where the lowermost layer is located closest to the piezoelectric film, is a strontium ruthenate film or a lanthanum nickelate film.

For an embodiment of the die according to the present invention, it is preferable from the viewpoint of piezoelectric properties that an upper surface of the first electrode is covered with a protective film, and the protective film is a zirconium dioxide film, an aluminum oxide film, a hafnium oxide film, an yttrium oxide film, or an aluminum nitride film.

A method for manufacturing a die according to an embodiment of the present invention is a method for manufacturing a die using a Si substrate. The method comprises at least steps of: forming a stacked body that includes the die according to one of the embodiments of the present invention on the Si substrate; and cutting the stacked body to individualize the die, wherein an acute angle θ3 between a fourth direction and a fifth direction is within a range of 0 to 15° where the fourth direction is a vertical direction of a notch or an orientation flat of the Si substrate and the fifth direction is a cutting direction forming a smallest angle with the fourth direction among cutting directions in the cutting.

For an embodiment of the method for manufacturing a die according to the present invention, it is preferable that the acute angle θ3 is within a range of 0 to 5° from the viewpoint that the acute angle θ1 or the acute angle θ2 can be made within a range of 40 to 50°.

The droplet ejection head according to an embodiment of the present invention includes the die according to one of the embodiments of the present invention.

The droplet ejection device according to an embodiment of the present invention includes the droplet ejection head according to the embodiment of the present invention.

Hereinafter, the present invention, constituent elements thereof, and forms and aspects for carrying out the present invention will be described in detail. In the present description, when two figures are used to indicate a range of value before and after “to”, these figures are included in the range as a lower limit value and an upper limit value.

<1. Overview of Die according to Embodiments of Present Invention>

The die according to one embodiment of the present invention comprises one or more piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ1 between a first direction and a second direction is within a range of 30 to 60° where the first direction is a longitudinal direction of the hollow portion as viewed from the out-of-plane direction of the main surface of the piezoelectric film and the second direction is a [100] direction of the piezoelectric film.

The die according to another embodiment of the present invention comprises a plurality of piezoelectric actuators each including a piezoelectric element and having a hollow portion, the hollow portion serving as a pressure chamber, wherein: the piezoelectric element includes at least a piezoelectric film, a first electrode disposed on the piezoelectric film, and a second electrode disposed under the piezoelectric film; the one or more piezoelectric actuators each includes a vibration plate that also serves as the second electrode or that is a discrete component disposed under the second electrode; the hollow portion is located under the second electrode that also serves as the vibration plate or under the separate vibration plate as the discrete component; the piezoelectric film has a main surface that is a (001) plane and crystal orientations aligned in an out-of-plane direction of the main surface and in an in-plane direction of the main surface; and an acute angle θ2 between a third direction and a second direction is within a range of 30 to 60° where the third direction is a [100] direction in which the plurality of piezoelectric actuators are arranged and the second direction is a [100] direction of the piezoelectric film.

In the present invention, the term “piezoelectric element” refers to an element that includes a first electrode, and a second electrode not electrically connected to the first electrode, with a piezoelectric material sandwiched between the first electrode and the second electrode.

In the present invention, the term “piezoelectric actuator” refers to an element that includes a piezoelectric element and is intended to utilize resulting displacement by changing the shape of the piezoelectric element by application of a voltage between the first electrode and the second electrode. The piezoelectric actuator also includes a diaphragm structure in which a vibration plate is bonded to the piezoelectric element.

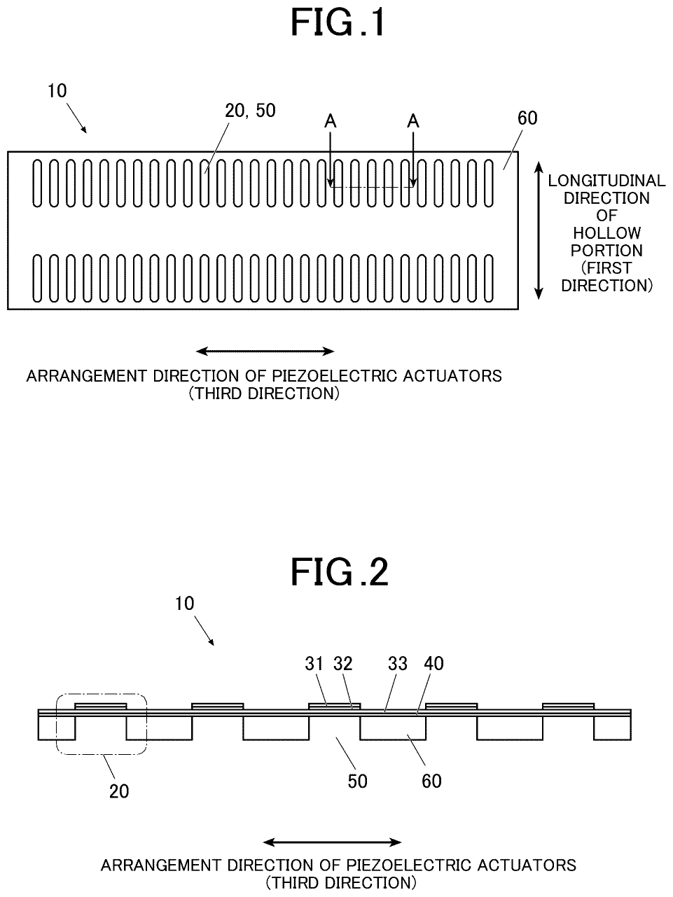

FIG. 1 is a schematic plan view of a die 10 according to an embodiment of the present invention as viewed from bottom (side facing hollow portions). When the die 10 is viewed from the bottom (side facing the hollow portions) as illustrated in FIG. 1, a pressure chamber member 60 and hollow portions 50 of piezoelectric actuators 20 are seen as the main components. In the die 10 shown in FIG. 1, the hollow portions 50 of the piezoelectric actuators 20 are arranged in two rows.

FIG. 2 is a schematic cross-sectional view of a part of the die 10 according to the embodiment of the present invention, and corresponds to the A-A cross section of FIG. 1. FIG. 2 illustrates, as a part of the die 10, a region in which five piezoelectric actuators 20 are arranged. Each of the piezoelectric actuators 20 illustrated in FIG. 2 includes a piezoelectric element 30, a vibration plate 40 disposed under the piezoelectric element 30, a hollow portion 50 located under the vibration plate 40, and a pressure chamber member 60 forming the hollow portion 50.

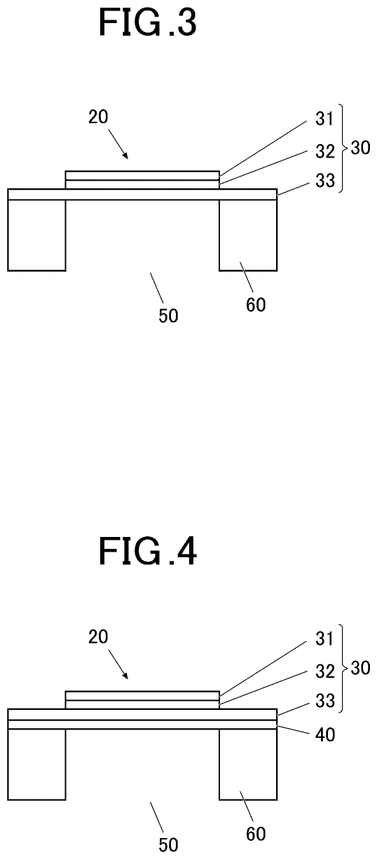

The piezoelectric actuator according to the embodiment of the present invention is characterized in that the second electrode also serves as a vibration plate, or a vibration plate is separately provided under the second electrode. When the second electrode also serves as a vibration plate, the piezoelectric actuator has, for example, a layer structure illustrated in FIG. 3. The piezoelectric actuator 20 illustrated in FIG. 3 includes a piezoelectric element 30 that includes a first electrode 31, a piezoelectric film 32, and a second electrode 33 that also serves as a vibration plate, and a hollow portion 50 located thereunder. In addition, in a case where a vibration plate is separately provided under the second electrode, the piezoelectric actuator includes, for example, a layer configuration illustrated in FIG. 4. The piezoelectric actuator 20 illustrated in FIG. 4 includes a piezoelectric element 30 that includes a first electrode 31, a piezoelectric film 32, and a second electrode 33, a vibration plate 40 disposed thereunder, and a hollow portion 50 located thereunder.

In the present invention, the piezoelectric film 32 is characterized in that crystal orientations are aligned in an out-of-plane direction of the main surface (hereinafter, also simply referred to as “out-of-plane direction”) and an in-plane direction of the main surface (hereinafter, also simply referred to as “in-plane direction”). Here, the term “main surface” in the present invention refers to a surface that has the largest surface area.

Furthermore, in the present invention, a “crystal plane” and a “crystal orientation” of a crystal forming the piezoelectric film 32 are expressed using Miller Indices. A crystal is a collection of unit cells, which are made up of a collection of planes formed by atoms. A plane formed by these atoms is referred to as a “crystal plane”. In addition, a crystal is configured such that crystal planes are arranged in parallel at equal intervals, and a direction in which the crystal planes are arranged (a direction perpendicular to the crystal planes) is referred to as a “crystal orientation”. A crystal plane is expressed using a plane index of Miller indices as a (100) plane, a (110) plane, or the like. In addition, a crystal orientation is expressed as a [100] direction or the like using a direction index (orientation index) of Miller indices.

As a reference of Miller indices in the present invention, the main surface of the piezoelectric film 32 is defined as a (001) plane. That is, an out-of-plane direction which is a normal direction of the (001) plane is a [001] direction, and a direction perpendicular to a (100) plane or a (010) plane among in-plane directions parallel to the main surface of the piezoelectric film 32 is a [100] direction or a [0110] direction, respectively. The [100] direction and the [010] direction of the piezoelectric film 32 are indistinguishable due to the rotational symmetry of the crystal.

In the present invention, it can be confirmed by, for example, X-ray diffraction (XRD) measurement that crystal orientations are aligned in an out-of-plane direction of the main surface and an in-plane direction of the main surface.

The hollow portion 50 of the piezoelectric actuator 20 according to the embodiment of the present invention has a shape having a longitudinal direction and a lateral direction, such as an oval, a rectangle, an ellipse, or a rhombus, when viewed from the out-of-plane direction of the main surface of the piezoelectric film 32. An object of the present invention is to suppress occurrence of a crack in the piezoelectric film 32 of the piezoelectric actuator 20 having the hollow portion 50 of such a shape.

### <2. Acute Angles θ1 and θ2>

The die according to the embodiment of the present invention is characterized in that, when a longitudinal direction of the hollow portion 50 as viewed from an out-of-plane direction of the main surface of the piezoelectric film 32 is defined as a first direction and the [100] direction of the piezoelectric film 32 is defined as a second direction, the acute angle θ1 between the first direction and the second direction is within a range of 30 to 60°. In addition, the die according to the embodiment of the present invention is characterized in that, when a direction in which the plurality of piezoelectric actuators 20 are arranged is defined as a third direction, and the [100] direction of the piezoelectric film 32 is defined as the second direction, the acute angle θ2 between the third direction and the second direction is within a range of 30 to 60°.

As described above, the present inventors have found that, in the hollow portion 50 of the piezoelectric actuator 20, the piezoelectric film 32 is more likely to be cracked in the longitudinal direction and the lateral direction, that is, the piezoelectric film 32 is more likely to be cracked in the first direction and the in-plane perpendicular direction to the first direction. Note that in FIG. 1, the vertical direction of the figure is the first direction, and in FIG. 2, the depth direction of the figure is the first direction.

Furthermore, as described above, the present inventors have found that the piezoelectric film 32 tends to crack in the direction in which the plurality of piezoelectric actuators 20 are arranged, that is, the piezoelectric film 32 tends to crack in the third direction. In the die, when there are two or more directions in which the plurality of piezoelectric actuators is arranged, the direction in which the piezoelectric actuators are arranged at closer intervals is defined as the third direction. In FIGS. 1 and 2, the horizontal direction of the drawings is the third direction.

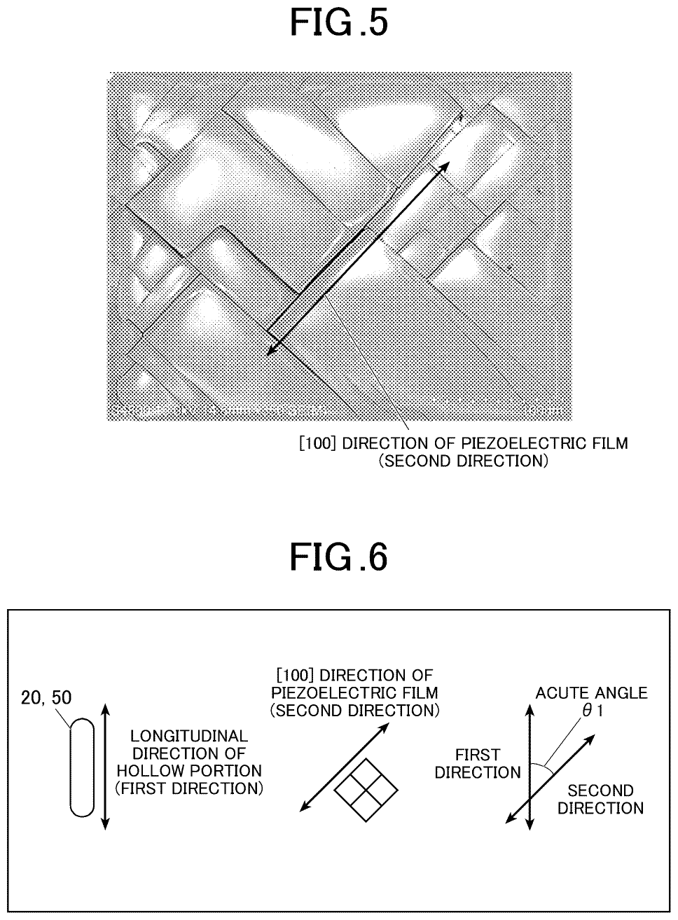

Further, as described above, the present inventors have found that, in the piezoelectric film 32 in which the crystal structure is aligned in the in-plane direction, cracks are likely to occur in the [100] direction and the [010] the direction of the piezoelectric film 32, that is, cracks are likely to occur in the second direction and the in-plane perpendicular direction to the second direction in the piezoelectric film 32. FIG. 5 is an electron micrograph in which cracks generated in the [100] direction (second direction) and the [010] direction (in-plane perpendicular direction to the second direction) of the piezoelectric film 32 are observed. In the piezoelectric film 32 in which the crystal structure is aligned in the in-plane direction, cracks as illustrated in FIG. 5 tend to occur.

FIG. 6 is a diagram illustrating the acute angle θ1. As illustrated in FIG. 6, in the present invention, an acute angle between the longitudinal direction (first direction) of the hollow portion as viewed from the out-of-plane direction of the main surface of the piezoelectric film and the [100] direction (second direction) of the piezoelectric film is defined as the acute angle θ1.

The die according to the embodiment of the present invention is characterized in that the acute angle θ1 is within a range of 30 to 60°. This makes it possible to cause a difference between a direction in which a crack is likely to occur from the viewpoint of the shape of the piezoelectric actuator and a direction in which a crack is likely to occur from the viewpoint of the crystal structure of the piezoelectric film, thereby suppressing the occurrence of a crack. From the viewpoint of further suppressing the occurrence of a crack, the acute angle θ1 is preferably within a range of 40 to 50°.

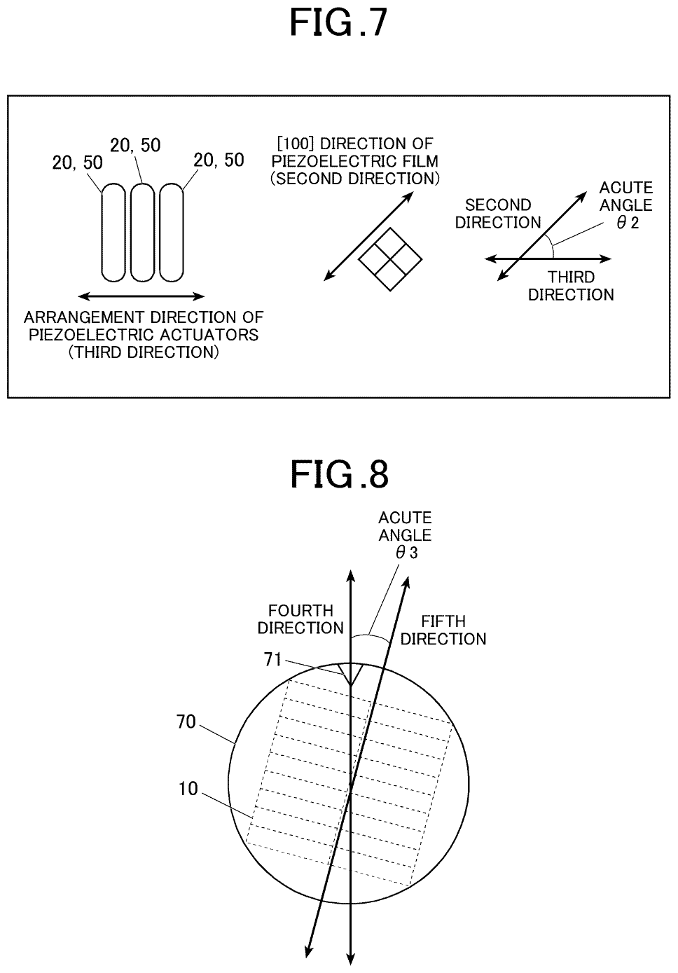

FIG. 7 is a diagram illustrating the acute angle θ2. As illustrated in FIG. 7, in the present invention, an acute angle between the direction (third direction) in which the plurality of piezoelectric actuators is arranged and the [100] direction (second direction) of the piezoelectric film is defined as the acute angle θ2.

The die according to the embodiment of the present invention is characterized in that the acute angle θ2 is within a range of 30 to 60°. This makes it possible to cause a difference between a direction in which a crack is likely to occur from the viewpoint of the arrangement of the piezoelectric actuators and a direction in which a crack is likely to occur from the viewpoint of the crystal structure of the piezoelectric film, thereby suppressing the occurrence of a crack. From the viewpoint of further suppressing the occurrence of a crack, the acute angle θ2 is preferably within a range of 40 to 50°.

Furthermore, for the die according to the embodiment of the present invention, it is more preferable that both of the acute angle θ1 and the acute angle θ2 are within a range of 30 to 60°, and it is particularly preferable that both of the acute angle θ1 and the acute angle θ2 are within a range of 40 to 50°.

In the present invention, the [100] direction (second direction) of the piezoelectric film 32 can be identified from a diffraction pattern obtained by in-plane measurement of an X-ray diffraction (XRD) method.

### <3. Configuration of Die>

As described above with reference to FIGS. 1 to 3, the die 10 according to the embodiment of the present invention includes one or more piezoelectric actuators 20 each having a piezoelectric element 30 and a hollow portion 50 that serves as a pressure chamber. The piezoelectric element 30 includes at least a piezoelectric film 32, a first electrode 31 disposed on the piezoelectric film 32, and a second electrode 33 disposed under the piezoelectric film 32. In addition, in the piezoelectric actuator, the second electrode 33 also serves as a vibration plate, or a vibration plate 40 is separately provided under the second electrode 33. In addition, the hollow portion 50 is located under the second electrode 33 that also serves as a vibration plate or under the vibration plate 40 that is separately provided.

In the piezoelectric element according to the embodiment of the present invention, the distance between the first electrode and the second electrode is preferably within a range of 0.1 to 5 μm from the viewpoint of a displacement generating force required of the piezoelectric element.

The material of the piezoelectric film is not particularly limited as long as it is a piezoelectric material. The crystal structure is preferably a perovskite structure.

The term “perovskite structure” refers to a crystal structure similar to that of perovskite (perovskite CaTiO₃). Usually, the composition of a perovskite crystal structure is represented by ABX₃. In the perovskite crystal structure, A, B, and X are present as constituent ions of an A cation, a B cation, and an X anion, respectively. In addition, a B cation-defective perovskite compound, an A cation-defective perovskite compound, and an X anion-defective perovskite compound are also defined as compounds having a perovskite crystal structure in the present invention. Among the perovskite structures, a perovskite structure represented by a ABO₃, in which X in the ABX₃ is oxygen (O), is preferable.

Examples of the piezoelectric film made of a piezoelectric material having a perovskite crystal structure represented by ABO₃ include a lead zirconate titanate (PZT: Pb(Zr, Ti)O₃) film, a lead titanate (PbTiO₃) film, a lead zirconate (PbZrO₃) film, a lead lanthanum titanate (PLT: (Pb, La)TiO₃) film, and a barium titanate (BaTiO₃) film.

Among these, a lead zirconate titanate film is preferable from the viewpoint of piezoelectric properties. Specifically, a lead zirconate titanate film represented by Pb_{X}(Zr_{Y}, Ti_{1-y}) O₃ [1.0≤X≤1.2, 0.4≤Y≤0.6]) is preferable. Furthermore, in the lead zirconate titanate film, Y is preferably within a range of 0.50 to 0.58, and particularly preferably 0.52 from the viewpoint of piezoelectric properties.

It is preferable that the lead zirconate titanate film has a non-stoichiometric composition. Specifically, when the composition is represented by Pb_{X}(Zr_{Y}, Ti_{1-Y})O₃ [1.0≤X≤1.2, 0.4≤Y≤0.6]), it is preferable that X>1.

The materials of the first electrode and the second electrode are not particularly limited, and Cr, Ni, Cu, Pt, Ir, Ti, an Ir—Ti alloy, LaNiO₃, SRO (SrRuO₃), STO (SrTiO₃), or the like can be used. Each of the first electrode and the second electrode may have a multilayer structure including two or more electrodes.

It is preferable that at least one of the first electrode or the second electrode includes a Pt electrode. It is preferable that the Pt electrode has the main surface of a (001) plane and has crystal orientations aligned in an in-plane direction and an out-of-plane direction. When one of the first electrode and the second electrode includes a Pt electrode, it is preferable that the other includes a Cu electrode.

Furthermore, the first electrode or the second electrode preferably has a multilayer structure including a plurality of different electrodes. In particular, it is preferable that the first electrode has a multilayer structure and the lowermost layer of the multilayered first electrode, where the lowermost layer is located closest to the piezoelectric film, has crystal orientations aligned in an out-of-plane direction and an in-plane direction. Furthermore, from the viewpoint of piezoelectric properties, it is preferable that the aligned out-of-plane crystal orientation of the piezoelectric film and the aligned out-of-plane crystal orientation of the lowermost layer of the first electrode coincide with each other, and the aligned in-plane crystal orientation of the piezoelectric film and the aligned in-plane crystal orientation of the lowermost layer of the first electrode do not coincide with each other.

In the present invention, whether an out-of-plane crystal orientation of a certain layer coincides with an out-of-plane crystal orientation of another layer can be confirmed from a diffraction pattern obtained by in-plane measurement of an X-ray diffraction (XRD) method.

Furthermore, in the present invention, whether an in-plane crystal orientation of a layer coincides with an in-plane crystal orientation of another layer can be confirmed from a diffraction pattern obtained by in-plane measurement of an X-ray diffraction (XRD) method.

When the first electrode has a multilayer structure, the lowermost layer of the multilayered first electrode, where the lowermost layer is located closest to the piezoelectric film, preferably has a perovskite structure represented by ABO₃. For example, a strontium rutheniumate (SrRuO₃) film or a lanthanum nickelate (LaNiO₃) film is preferable from the viewpoint of piezoelectric properties.

In the piezoelectric actuator according to the embodiment of the present invention, the second electrode also serves as a vibration plate, or a vibration plate is separately provided under the second electrode. For the material of the separately provided vibration plate, the same material as that of the second electrode can be used.

From the viewpoint of the dielectric constant, the piezoelectric element according to the embodiment of the present invention preferably has a dielectric film between the piezoelectric film and the second electrode. The dielectric film is not particularly limited as long as it is made of a dielectric material, but preferably has a lower dielectric constant than the piezoelectric film.

The dielectric film preferably has a perovskite structure whose crystal structure is represented by ABO₃ and is preferably a lead lanthanum titanate film. Examples of the dielectric film having a perovskite structure in which the crystal structure is represented by ABO₃ include a lead titanate (PbTiO₃) film, a lead lanthanum titanate (PLT: (Pb, La)TiO₃) film, and a barium titanate (BaTiO₃) film. Among these, a film that includes lead is preferable, and a lead lanthanum titanate film is particularly preferable from the viewpoint of the dielectric constant.

From the viewpoint of the dielectric constant, crystal orientations of the dielectric film are preferably aligned in an out-of-plane direction of the main surface and an in-plane direction of the main surface. Furthermore, it is more preferable that the aligned out-of-plane crystal orientation of the piezoelectric film and the aligned out-of-plane crystal orientation of the dielectric film coincide with each other, and the aligned in-plane crystal orientation of the piezoelectric film and the aligned in-plane crystal orientation of the dielectric film also coincide with each other.

The root mean square (RMS) value of the surface roughness of the dielectric film on the side facing the second electrode is preferably 5.0 nm or less, more preferably 2.0 nm or less, and still more preferably 1.6 nm or less. This improves reliability and film adhesion in long-term driving.

The RMS value of the surface roughness can be measured using, for example, an atomic force microscope (Dimension Icon manufactured by BRUKER).

The piezoelectric element according to the embodiment of the present invention has a dielectric film between the piezoelectric film and the second electrode. When the first electrode has a multilayer structure, it is preferable from the viewpoint of piezoelectric properties that the piezoelectric film, the dielectric film, and the lowermost layer of the multilayered first electrode, where the lowermost layer is located closest to the piezoelectric film, all have a perovskite structure represented by ABO₃.

Further, in the piezoelectric element according to the embodiment of the present invention, an upper surface of the first electrode is preferably covered with a protective film. The protective film is preferably a zirconium dioxide (ZrO₂) film, an aluminum oxide (Al₂O₃) film, a hafnium oxide (HfO₂) film, an yttrium oxide (Y₂O₃) film, or an aluminum nitride (AlN) film from the viewpoint of piezoelectric properties. Further, a protective film made of a photosensitive polyimide resin or the like may be further provided on the protective film.

### <4. Method for Manufacturing Die>

The method for manufacturing a die according to the embodiment of the present invention is not particularly limited. However, as an example of the manufacturing method, a manufacturing method that includes at least a step of forming a stacked body that includes the die on a Si substrate (stacked body forming step), and a step of cutting the stacked body to individualize the die (die individualization step) will be described below.

In the stacked body forming step, each layer constituting the die is formed and stacked on the Si substrate by a known method such as a sputtering method. In this step, in order to form a layer in which crystal orientations are aligned in an out-of-plane direction of the main surface and an in-plane direction of the main surface, it is necessary for crystals to epitaxially grow. The term “epitaxially grow” means that crystals grow in a specific direction based on the regularity of the atomic arrangement of crystals in the underlying layer.

Each layer is patterned as necessary. Furthermore, for the Si substrate, not only a Si layer but also a commercially available substrate that has the first electrode and the like already formed on the Si layer may be used, and a necessary layer such as the piezoelectric film may be stacked thereon.

It is preferable that the Si substrate has crystal orientations aligned in an in-plane direction and an out-of-plane direction and has notches or orientation flats indicating the crystal orientations.

The stacked body formed on the Si substrate may be a stacked body from which only one die is obtained after individualization, or may be a stacked body in which a plurality of dies are arranged on a plane so that the plurality of dies are obtained after individualization. Normally, unless there is a problem due to the size of the Si substrate, a stacked body is formed such that a plurality of dies can be obtained.

In addition, a pressure chamber member is stacked under the second electrode that also serves as a vibration plate or under a vibration plate that is separately provided to form a hollow portion that serves as a pressure chamber. An ink blocking film or a seed layer may be formed between the vibration plate and the pressure chamber member.

In the die individualization step, the stacked body is cut to individualize the die. In this step, when the vertical direction of a notch or an orientation flat of the Si substrate is defined as a fourth direction, and when a cutting direction forming the smallest angle with the fourth direction among cutting directions in the die individualization step is defined as a fifth direction, the acute angle θ3 between the fourth direction and the fifth direction is preferably within a range of 0 to 15°, more preferably within a range of 0 to 5°, and particularly preferably 0°.

Here, the term “vertical direction of a notch or an orientation flat” refers to a direction from the center of the notch or orientation flat toward the center of the Si substrate.

FIG. 8 is a diagram illustrating the fourth direction, the fifth direction, and the acute angle θ3 between the fourth direction and the fifth direction. FIG. 8 shows a Si substrate 70 having a notch 71, and cutting lines (dashed lines) of a stacked body running along the contours of the 18 dies 10. As illustrated in FIG. 8, when the Si substrate 70 has the notch 71, the vertical direction of the notch 71 is the fourth direction. Furthermore, a cutting direction that forms the smallest angle with the fourth direction among cutting directions is the fifth direction.

Note that although FIG. 8 illustrates the case where the acute angle θ3 is 15° for ease of illustration, the acute angle θ3 is preferably as small as possible. Specifically, as described above, the acute angle θ3 is preferably within a range of 0 to 15°, more preferably within a range of 0 to 5°, and particularly preferably 0°.

Since the acute angle θ3 is small, in a case where: the vertical direction (fourth direction) of the notch or orientation flat indicates a [100] direction of the Si substrate; the [100] direction of the Si substrate and the [100] direction (second direction) of the piezoelectric film have a deviation of about 45°; and the cutting direction (fifth direction) and the longitudinal direction (first direction) of the hollow portion are perpendicular or parallel to each other, the acute angle θ1 between the first direction and the second direction becomes close to 45°, thereby suppressing the occurrence of a crack. Alternatively, in a case where: the vertical direction (fourth direction) of the notch or the orientation flat indicates the [100] direction of the Si substrate; the [100] direction of the Si substrate and the [100] direction (second direction) of the piezoelectric film have a deviation of about 45°; and the cutting direction (fifth direction) and the direction (third direction) in which the plurality of piezoelectric actuators are arranged are perpendicular or parallel to each other, the acute angle θ2 between the third direction and the second direction becomes close to 45°, thereby suppressing the occurrence of a crack.

The [100] direction of the Si substrate can also be identified from a diffraction pattern measured by an XRD method. The cutting directions for manufacturing the die according to the embodiment of the present invention can be easily determined by using the notch or the orientation flat as a reference.

Note that a [100] direction and a [010] direction of the Si substrate are indistinguishable because Si is in a cubic phase and has the rotational symmetry.

### <5. Applications of Die>

The die according to the embodiment of the present invention can be used, for example, as a droplet ejection head chip in combination with a nozzle plate or the like in a droplet ejection head or a droplet ejection device that includes the droplet ejection head.

The droplet ejection head and the droplet ejection device provided with the die according to the embodiment of the present invention are excellent in ejection stability because occurrence of a crack in a piezoelectric film is suppressed.

In addition to the above, the die according to the embodiment of the present invention can be used for a piezoelectric micromachined ultrasonic transducer (p-MUT), a microphone, a speaker, and the like.

### Example

Hereinafter, the present invention will be specifically described with reference to Examples, but the present invention is not limited thereto. In the examples, “part(s)” or “%” means “part(s) by mass” or “mass %” unless otherwise specified.

Dies Nos. 1 to 3 (the present invention) and a die No. 4 (comparative example) were produced, and the number of cracks generated in each of these dies was measured.

### <Preparation of Die No. 1>

As the Si substrate, an 8-inch Si substrate (manufactured by KRYSTAL) having a notch whose vertical direction (fourth direction) indicated the [100] direction of the Si substrate and in which layers had been formed in the order of SRO/Pt/ZrO₂/Si was used. In the Si substrate, the Pt layer and the SRO layer correspond to the first electrode that includes two layers of a Pt electrode and an SRO electrode. Furthermore, in the substrate, the ZrO₂ layer corresponds to a protective film (zirconium dioxide film) covering an upper surface of the first electrode. Each layer of the substrate has crystal orientations aligned in an in-plane direction and an out-of-plane direction. The main surface of each layer of the substrate is a (001) plane.

On the SRO layer of the Si substrate, a PZT film serving as the piezoelectric film was formed by an RF magnetron sputtering method. As the PZT ceramic target, a PZT ceramic target having an excess lead composition (Pb_{1.25}(Zr_{0.52}, Ti_{0.48})O₃)) containing 25% more Pb than the stoichiometric composition was used. The PZT film was formed such that an acute angle between the [100] direction of the Si layer and a [100] direction of the PZT film was 45°. The [100] direction of the PZT film is the second direction in the present invention.

The thickness of the PZT film and the sputtering conditions were as follows.
Thickness . . . 3.38 μm
RF power supply . . . 3.0 kW
Gas flow rate . . . Ar: O₂=39.5:0.5 sccm
Sputtering pressure . . . 0.2 Pa
Substrate set temperature . . . 550° C.

In the above-described PZT film forming step, the PZT film was formed in two separate steps, and cleaning was performed between the first and second steps.

Next, a PLT film serving as the dielectric film was formed on the PZT film by an RF magnetron sputtering method. As the PZT ceramic target, a PZT ceramic target having an excess lead composition ((Pb_{1.125}, La_{0.1})TiO₃) containing 25% more Pb than the stoichiometric composition of Pb:La=0.9:0.1 was used.

The thickness of the PLT film and the sputtering conditions are as follows.
Thickness . . . 0.12 μm
RF power supply . . . 2.0 kW
Gas flow rate . . . Ar: O₂=39.5:0.5 sccm
Sputtering pressure . . . 0.2 Pa
Substrate set temperature . . . 560° C.

Next, the second electrode was formed on the dielectric film (PLT film) by a sputtering method using a Cu target. The thickness and the sputtering conditions are as follows. Note that the second electrode also serves as a vibration plate in the piezoelectric actuator.
Thickness . . . 2.8 μm
DC power supply . . . 1 kW
Gas flow rate . . . Ar=50 sccm
Sputtering pressure . . . 0.15 Pa
Substrate set temperature . . . room temperature

Next, a photosensitive polyimide resin was applied onto the second electrode by a spin coating method and cured by baking at 230° C. to form the ink blocking film of 1 μm.

Next, the seed layer of 0.5 μm was formed on the ink blocking film by a sputtering method using a Ni target. The sputtering was performed for 15 minutes in an argon gas at a high frequency power of 500 W and a sputtering gas pressure of 1 Pa.

Next, the hollow portions (portions serving as pressure chambers) were formed. Each of the hollow portions has an oval shape, and has the height of 150 μm, the length in the lateral direction of 120 μm, and the length in the longitudinal direction of 1250 μm. Specifically, two layers of 80 μm-thick dry film resist (ORDYL MP108 manufactured by TOKYO OHKA KOGYO CO., LTD.) were formed, and then the pressure chamber member made of Ni was deposited by Ni electroforming. Next, the dry film resist layers were removed, and the resultant was washed and dried to form the hollow portions.

In this step, the hollow portion was formed such that the acute angle θ1 between the longitudinal direction (first direction) of the hollow portion and the [100] direction (second direction) of the PZT film was 30°.

Further, 400 hollow portions were formed per die such that 200 piezoelectric actuators each having a hollow portion were arranged in two rows in one die. The direction in which 200 piezoelectric actuators were arranged in this step was the third direction, and here, the third direction was an in-plane perpendicular direction with respect to the first direction. That is, in the die No. 1, the acute angle θ2 between the direction (third direction) in which the plurality of piezoelectric actuators is arranged and the [100] direction (second direction) of the piezoelectric film was 60°.

Next, an 8-inch support substrate made of glass was attached to the pressure chambers with a double-sided thermal release sheet manufactured by NITTO DENKO.

Next, the Si layer was ground to a thickness of about 50 μm, and then completely removed by dry etching using SF₆.

Next, an OMR resist manufactured by TOKYO OHKA KOGYO CO., LTD. was applied onto the ZrO₂ film, and a mask pattern was transferred by exposure and developed to form a resist mask. Next, the ZrO₂ film and the first electrode thereunder in a region where the resist mask was not formed were removed by dry etching using a mixed gas of argon, oxygen, and CHF 3. After cleaning, the resist mask was peeled using a peeling solution.

Next, an OMR resist manufactured by TOKYO OHKA KOGYO CO., LTD. was applied, and a mask pattern was transferred by exposure and developed to form a resist mask. Next, the piezoelectric film (PZT film) and the dielectric film (PLT film) in a region where the resist mask was not formed were removed by dry etching using a mixed gas of chlorine and bromine. After cleaning, the resist mask was peeled using a peeling solution.

Next, on the protective film (ZrO₂), a 1 μm-thick protective film was further formed by applying a photosensitive polyimide resin by a spin coating method and further patterning the photosensitive polyimide resin. The patterning was performed by transferring a mask pattern by exposure and developing the mask pattern. After the patterning, the resultant was baked at 210° C. to be cured.

Next, the die individualization step was performed. In the die individualization step, the stacked body was cut such that the acute angle θ3 between the vertical direction (fourth direction) of the notch of the Si substrate and the cutting direction (fifth direction) forming the smallest angle with the fourth direction among the cutting directions was 15°.

Next, the support substrate was heated to a temperature equal to or higher than the temperature at which the thermal release sheet foamed, and the support substrate was removed to obtain the die No. 1 that includes a plurality of (400) piezoelectric actuators.

### <Preparation of Die Nos. 2 to 4>

The dies Nos. 2 to 4 were produced in the same manner as the die No. 1 except that the acute angle θ1, the acute angle θ2, and the acute angle θ3 were changed as described in Table I.

### [Table 1]

TABLE I

| | | | | NUMBER | |
|---|---|---|---|---|---|
| | | | | OF | |
| | θ 1 | θ 2 | θ 3 | CRACKS | REMARKS |
| DIE No. 1 | 30° | 60° | 15° | 3 | PRESENT |
| | | | | | INVENTION |
| DIE No. 2 | 40° | 50° | 5° | 1 | PRESENT |
| | | | | | INVENTION |
| DIE No. 3 | 45° | 45° | 0° | 1 | PRESENT |
| | | | | | INVENTION |
| DIE No. 4 | 20° | 70° | 25° | 12 | COMPARATIVE |
| | | | | | EXAMPLE |

### <Evaluation of Crack Suppression>

A positive voltage of 40 V was applied to the first electrode of each piezoelectric actuator of the dies for 1 minute. Thereafter, the surfaces of the piezoelectric films of all the piezoelectric actuators were observed, and the number of cracks generated in the piezoelectric films per 400 piezoelectric actuator was measured. The results are listed in Table I.

In the die No. 4 in which the acute angle θ1 was 20°, the number of cracks was 12, whereas in the die No. 1 in which the acute angle θ1 was 30°, the number of cracks was 3, so that cracks were significantly suppressed. Furthermore, in the die No. 2 in which the acute angle θ1 was 40° and the die No. 3 in which the acute angle θ1 was 45°, the number of cracks was 1, and cracks were more significantly suppressed.

Similarly, in the die No. 4 in which the acute angle θ2 was 70°, the number of cracks was 12, whereas in the die No. 1 in which the acute angle θ2 was 60°, the number of cracks was 3, so that cracks were significantly suppressed. Furthermore, in the die No. 2 in which the acute angle θ2 was 50° and the die No. 3 in which the acute angle θ2 was 45°, the number of cracks was 1, and cracks were more significantly suppressed.

In addition, focusing on the die individualization step, in the die No. 4 in which the acute angle θ3 was 25°, the number of cracks was 12, whereas in the die No. 1 in which the acute angle θ3 was 15°, the number of cracks was 3, so that cracks were significantly suppressed. Furthermore, in the die No. 2 in which the acute angle θ3 was 5° and the die No. 3 in which the acute angle θ3 was 0°, the number of cracks was 1, and cracks were more significantly suppressed.

### INDUSTRIAL APPLICABILITY

The present invention can be used for a die in which the occurrence of a crack is suppressed, a method for manufacturing the die, and a liquid droplet ejection head and a liquid droplet ejection device that includes the die.

### REFERENCE SIGNS LIST

10 die
20 piezoelectric actuator
30 piezoelectric element
31 first electrode
32 piezoelectric film
33 second electrode
40 vibration plate
50 hollow portion
60 pressure chamber member
70 Si substrate
71 notch

1. A die comprising one or more piezoelectric actuators each including a piezoelectric element and having a hollow portion, the hollow portion serving as a pressure chamber, wherein:
the piezoelectric element includes at least a piezoelectric film, a first electrode disposed on the piezoelectric film, and a second electrode disposed under the piezoelectric film;
the one or more piezoelectric actuators each includes a vibration plate that also serves as the second electrode or that is a discrete component disposed under the second electrode;
the hollow portion is located under the second electrode that also serves as the vibration plate or under the separate vibration plate as the discrete component;
the piezoelectric film has a main surface that is a (001) plane and crystal orientations aligned in an out-of-plane direction of the main surface and in an in-plane direction of the main surface; and
an acute angle θ1 between a first direction and a second direction is within a range of 30 to 60° where the first direction is a longitudinal direction of the hollow portion as viewed from the out-of-plane direction of the main surface of the piezoelectric film and the second direction is a [100] direction of the piezoelectric film.

2. The die according to claim 1, wherein the acute angle θ1 is within a range of 40 to 50°.

3. A die comprising a plurality of piezoelectric actuators each including a piezoelectric element and having a hollow portion, the hollow portion serving as a pressure chamber, wherein:
the piezoelectric element includes at least a piezoelectric film, a first electrode disposed on the piezoelectric film, and a second electrode disposed under the piezoelectric film;
the one or more piezoelectric actuators each includes a vibration plate that also serves as the second electrode or that is a discrete component disposed under the second electrode;
the hollow portion is located under the second electrode that also serves as the vibration plate or under the separate vibration plate as the discrete component;
the piezoelectric film has a main surface that is a (001) plane and crystal orientations aligned in an out-of-plane direction of the main surface and in an in-plane direction of the main surface; and
an acute angle θ2 between a third direction and a second direction is within a range of 30 to 60° where the third direction is a direction in which the plurality of piezoelectric actuators are arranged and the second direction is a [100] direction of the piezoelectric film.

4. The die according to claim 3, wherein the acute angle θ2 is within a range of 40 to 50°.

5. The die according to claim 1, wherein a distance between the first electrode and the second electrode in the piezoelectric element is within a range of 0.1 to 5 μm.

6. The die according to claim 1, wherein:
the piezoelectric element includes a dielectric film between the piezoelectric film and the second electrode;
the dielectric film has crystal orientations aligned in an out-of-plane direction of a main surface of the dielectric film and an in-plane direction of the main surface of the dielectric film;
the aligned out-of-plane crystal orientation of the piezoelectric film coincides with the aligned out-of-plane crystal orientation of the dielectric film; and
the aligned in-plane crystal orientation of the piezoelectric film coincides with the aligned in-plane crystal orientation of the dielectric film.

7. The die according to claim 1, wherein:
the first electrode has a multilayer structure;
a lowermost layer of the first electrode having the multilayer structure, the lowermost layer being closest to the piezoelectric film, has crystal orientations aligned in an out-of-plane direction of a main surface of the lowermost layer and an in-plane direction of the main surface of the lowermost layer;
the aligned out-of-plane crystal orientation of the piezoelectric film coincides with the aligned out-of-plane crystal orientation of the lowermost layer; and
the aligned in-plane crystal orientation of the piezoelectric film does not coincide with the aligned in-plane crystal orientation of the lowermost layer.

8. The die according to claim 1, wherein:
the piezoelectric element includes a dielectric film between the piezoelectric film and the second electrode;
the first electrode has a multilayer structure; and
the piezoelectric film, the dielectric film, and a lowermost layer of the first electrode having the multilayer structure, the lowermost layer being closest to the piezoelectric film, all have a perovskite structure represented by ABO₃.

9. The die according to claim 1, wherein the piezoelectric film is a lead zirconate titanate film.

10. The die according to claim 1, wherein:
the piezoelectric element includes a dielectric film between the piezoelectric film and the second electrode;
the dielectric film is a lead lanthanum titanate film;
the first electrode has a multilayer structure; and
a lowermost layer of the first electrode having the multilayer structure, the lowermost layer being closest to the piezoelectric film, is a strontium ruthenate film or a lanthanum nickelate film.

11. The die according to claim 1, wherein
an upper surface of the first electrode is covered with a protective film, and
the protective film is a zirconium dioxide film, an aluminum oxide film, a hafnium oxide film, an yttrium oxide film, or an aluminum nitride film.

12. (canceled)

13. (canceled)

14. A droplet ejection head comprising a die, wherein the die is the die according to claim 1.

15. (canceled)

16. The die according to claim 3, wherein a distance between the first electrode and the second electrode in the piezoelectric element is within a range of 0.1 to 5 μm.

17. The die according to claim 3, wherein:
the piezoelectric element includes a dielectric film between the piezoelectric film and the second electrode;
the dielectric film has crystal orientations aligned in an out-of-plane direction of a main surface of the dielectric film and an in-plane direction of the main surface of the dielectric film;
the aligned out-of-plane crystal orientation of the piezoelectric film coincides with the aligned out-of-plane crystal orientation of the dielectric film; and
the aligned in-plane crystal orientation of the piezoelectric film coincides with the aligned in-plane crystal orientation of the dielectric film.

18. The die according to claim 3, wherein:
the first electrode has a multilayer structure;
a lowermost layer of the first electrode having the multilayer structure, the lowermost layer being closest to the piezoelectric film, has crystal orientations aligned in an out-of-plane direction of a main surface of the lowermost layer and an in-plane direction of the main surface of the lowermost layer;
the aligned out-of-plane crystal orientation of the piezoelectric film coincides with the aligned out-of-plane crystal orientation of the lowermost layer; and
the aligned in-plane crystal orientation of the piezoelectric film does not coincide with the aligned in-plane crystal orientation of the lowermost layer.

19. The die according to claim 3, wherein:
the piezoelectric element includes a dielectric film between the piezoelectric film and the second electrode;
the first electrode has a multilayer structure; and
the piezoelectric film, the dielectric film, and a lowermost layer of the first electrode having the multilayer structure, the lowermost layer being closest to the piezoelectric film, all have a perovskite structure represented by ABO₃.

20. The die according to claim 3, wherein the piezoelectric film is a lead zirconate titanate film.

21. The die according to claim 3, wherein:
the piezoelectric element includes a dielectric film between the piezoelectric film and the second electrode;
the dielectric film is a lead lanthanum titanate film;
the first electrode has a multilayer structure; and
a lowermost layer of the first electrode having the multilayer structure, the lowermost layer being closest to the piezoelectric film, is a strontium ruthenate film or a lanthanum nickelate film.

22. The die according to claim 3, wherein
an upper surface of the first electrode is covered with a protective film, and
the protective film is a zirconium dioxide film, an aluminum oxide film, a hafnium oxide film, an yttrium oxide film, or an aluminum nitride film.

23. A droplet ejection head comprising a die, wherein the die is the die according to claim 3.
